(19) United States
(12) Patent Application Publication
(10) Pub. No.: US 2025/0389590 A1
(43) Pub. Date: Dec. 25, 2025

(54) TRANSISTORS WITH PYROELECTRIC MATERIAL LAYER FOR THRESHOLD VOLTAGE CONTROL

(71) Applicant: Intel Corporation, Santa Clara, CA (US)

(72) Inventors: Abhishek A. Sharma, Portland, OR (US); Tahir Ghani, Portland, OR (US); Pushkar Sharad Ranade, San Jose, CA (US); Anand S. Murthy, Portland, OR (US); Sagar Suthram, Portland, OR (US); Wilfred Gomes, Portland, OR (US)

(73) Assignee: Intel Corporation, Santa Clara, CA (US)

(21) Appl. No.: 18/748,360

(22) Filed: Jun. 20, 2024

(51) Int. Cl. G01J 5/20; H10N 30/85

(52) U.S. Cl. CPC G01J 5/20; H10N 30/85

(57) ABSTRACT

Transistors that include a pyroelectric dielectric layer, between the channel material and the gate electrode. The pyroelectric layer may have a crystal configuration that can be changed by applying a heat pulse. Different crystal configurations have different degrees of polarization, which result in different dielectric constants. The crystal configuration may be changed during operation using a heating element, thus switching a single device between two different threshold voltages.

### BACKGROUND

In integrated circuit (IC) devices, it is useful to include sets of transistors, where transistors in different sets have different threshold voltages (Vₜ). For example, high Vₜ transistors offer lower leakage, reduced power consumption, and improved stability. On the other hand, low Vₜ transistors, which turn on more easily, offer higher switching speed and higher performance. Transistors with different threshold voltages may be used for different applications, e.g., logic regions may use higher Vₜ transistors to save power, while access transistors in a memory region may use low Vₜ transistors for faster access times. Transistors with different threshold voltages may be achieved by varying doping concentrations in transistor channels, varying gate oxide thickness, varying transistor geometry (e.g., channel length and width), or other mechanisms. These techniques generally cause the Vₜ of a particular transistor to be fixed, e.g., dopant concentrations, gate oxide thickness, and transistor geometry cannot be changed after device fabrication.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a cross-section of an example transistor with a pyroelectric layer, according to some embodiments of the present disclosure.

FIGS. 2A-2C illustrate different crystal structures of pyroelectric materials, according to some embodiments of the present disclosure.

FIG. 3 is a cross-section of an example IC device that includes transistors with different transistor regions, according to some embodiments of the present disclosure.

FIG. 4 is a cross-section of two transistors with pyroelectric layers with different crystal structures, according to some embodiments of the present disclosure.

FIG. 5 is a flowchart illustrating a method for operating a transistor with a pyroelectric layer, according to some embodiments of the present disclosure.

FIGS. 6A and 6B are top views of a wafer and dies that include transistors with pyroelectric layers in accordance with any of the embodiments disclosed herein.

FIG. 7 is a cross-sectional side view of an IC device that may include one or more transistors with pyroelectric layers in accordance with any of the embodiments disclosed herein.

FIG. 8 is a cross-sectional side view of an IC device assembly that may include one or more transistors with pyroelectric layers in accordance with any of the embodiments disclosed herein.

FIG. 9 is a block diagram of an example computing device that may include one or more transistors with pyroelectric layers in accordance with any of the embodiments disclosed herein.

### DETAILED DESCRIPTION

### Overview

The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

Transistors that include a pyroelectric material are described herein. Pyroelectrics are a class of polar crystals that exhibit a coupling between electrical polarization and temperature, such that a change in temperature results in a change in the electric dipole moment, i.e., a change in the overall polarity of the material. For example, a high temperature induces a first crystal structure associated with a lower amount of polarization within the material; a low temperature induces a second crystal structure leads with a higher degree of polarization within the material.

When the pyroelectric material is used as the dielectric layer in a transistor device (e.g., as the material between a gate electrode and a semiconductor channel), the different crystal structures provide different threshold voltages. For example, a higher temperature causes a pyroelectric material to have an orthorhombic crystal structure, while a lower temperature causes the pyroelectric material to have a tetragonal crystal structure. As noted above, threshold voltage is related to power consumption of the transistor, as well as performance factors, such as switching speed. The higher-temperature orthorhombic material has a lower degree of polarization, which leads to a transistor with a higher threshold voltage. The higher threshold voltage is associated with lower leakage, reduced power consumption, and improved stability. The lower-temperature tetragonal material has a higher degree of polarization, which may lead to higher power consumption (e.g., due to leakage current), but also provides faster switching speed and access times.

For many applications, it is useful to include both high Vₜ and low Vₜ transistors in an electronic component, such as within a single die or chip. In other applications, it may be useful to change at least a portion of transistors in an IC device from a first Vₜ to a second, different Vₜ over time, e.g., from a lower Vₜ to a higher Vₜ as the device ages or degrades. As described herein, an IC device may have transistors with a pyroelectric layer as the gate dielectric. The transistors may be arranged in different regions, where a given region is thermally coupled to a heat source. A heat source may be used to change the crystal structure of the associated region of transistors. For example, a higher temperature pulse (e.g., 600° C.) may cause the pyroelectric layer to have an orthorhombic crystal structure, and a lower temperature pulse (e.g., 400° C.) may cause the pyroelectric layer to switch to a tetragonal crystal structure. The pulse durations may be different, e.g., the lower-temperature pulse may be at least twice as long as the higher-temperature pulse. The crystal structure may persist after the heat pulse has been applied. For example, a first, high-temperature pulse may induce an orthorhombic structure, which the pyroelectric layer maintains after cooling. Heating the pyroelectric layer again with the lower-temperature pulse may cause the crystal structure to shift to a tetragonal structure, which the pyroelectric layer maintains after cooling. At a given time, transistors in different device regions (e.g., different regions of a die) may have different crystal structures.

The transistors with pyroelectric layers described herein may be implemented in, or in combination with, more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

For purposes of explanation, specific numbers, materials and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well known features are omitted or simplified in order not to obscure the illustrative implementations.

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. The meaning of “a,” “an,” and “the” include plural references. The meaning of “in” includes “in” and “on.”

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. The terms “substantially,” “close,” “approximately,” “near,” and “about,” generally refer to being within +/−20% of a target value, unless specified otherwise. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, various aspects of the illustrative implementations will be described using terms commonly employed by those skilled in the art to convey the substance of their work to others skilled in the art. For example, as used herein, a “logic state” of a ferroelectric memory cell refers to one of a finite number of states that the cell can have, e.g. logic states “1” and “0,” each state represented by a different polarization of the ferroelectric material of the cell. In another example, as used herein, a “READ” and “WRITE” memory access or operations refer to, respectively, determining/sensing a logic state of a memory cell and programming/setting a logic state of a memory cell. In other examples, the term “connected” means a direct electrical or magnetic connection between the things that are connected, without any intermediary devices, while the term “coupled” means either a direct electrical or magnetic connection between the things that are connected or an indirect connection through one or more passive or active intermediary devices. The term “circuit” means one or more passive and/or active components that are arranged to cooperate with one another to provide a desired function. In yet another example, a “high-k dielectric” refers to a material having a higher dielectric constant (k) than silicon oxide. The terms “oxide,” “carbide,” “nitride,” etc. refer to compounds containing, respectively, oxygen, carbon, nitrogen, etc.

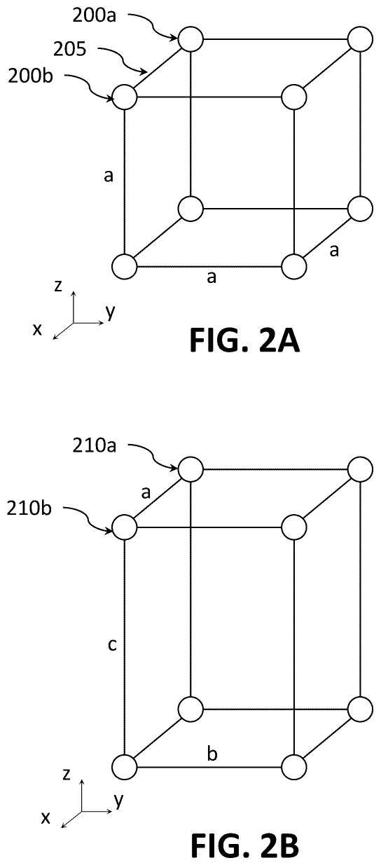

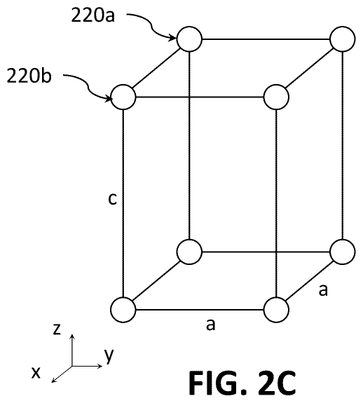

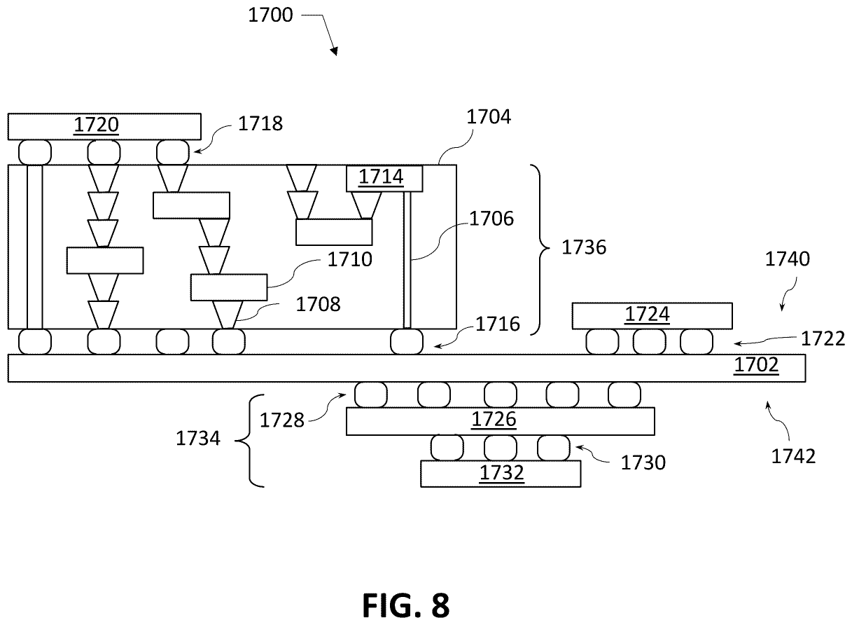

For convenience, if a collection of drawings designated with different letters are present, e.g., FIGS. 2A-2C, such a collection may be referred to herein without the letters, e.g., as “FIG. 8.”

### Example 1T-1C Memory Cell with Pyroelectric Capacitor

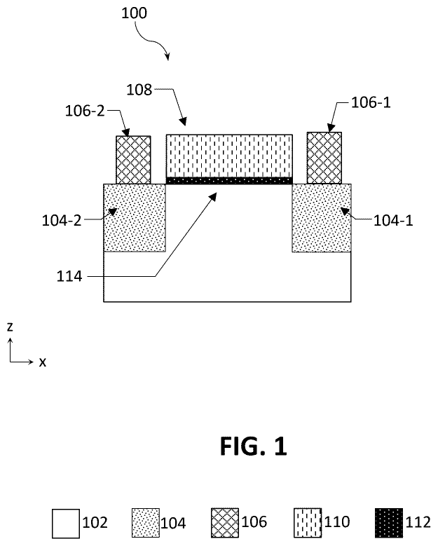

FIG. 1 is a cross-section of an example transistor 100 with a pyroelectric layer, according to some embodiments of the present disclosure. A number of elements referred to in the description of FIGS. 1, 3, and 4 with reference numerals are illustrated in these figures with different patterns, with a legend showing the correspondence between the reference numerals and patterns being provided at the bottom or side of each drawing page containing FIGS. 1, 3, and 4. For example, the legend under FIG. 1 illustrates that this figure uses different patterns to show a channel material 102, S/D regions 104, contacts 106, a gate electrode 110, and a pyroelectric material 112.

In the drawings, some example structures of various devices and assemblies described herein are shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

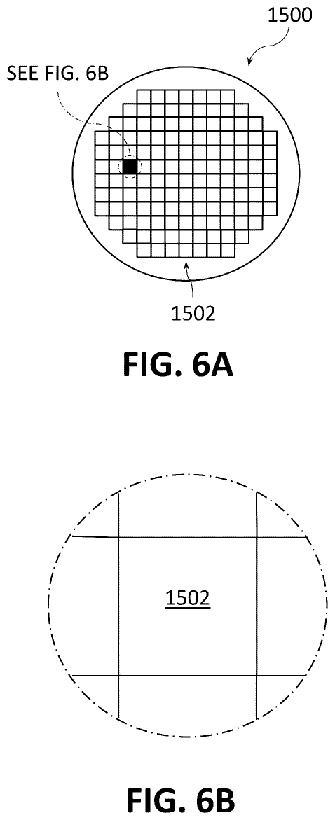

In general, implementations of the present disclosure may be formed or carried out on a support structure. The support structure may be, e.g., a substrate, a die, a wafer or a chip. For example, the support structure may be the wafer 1500 of FIG. 6A, discussed below, and may be, or be included in, a die, e.g., the singulated die 1502 of FIG. 6B, discussed below. The support structure extends along the x-y plane in the coordinate system shown in FIG. 1. In some embodiments, a support structure may be used during a fabrication process and later removed. In some embodiments, the channel material 102 is over the support structure. In other embodiments, the channel material 102 is a portion of the support structure, e.g., an upper portion of the support structure.

In some embodiments, the support structure may be a substrate that includes silicon and/or hafnium. More generally, the support structure may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support structure may be a printed circuit board (PCB) substrate. Although a few examples of materials from which the substrate may be formed are described here, any material that may serve as a foundation upon which a semiconductor device including one or more nanoribbon transistors, as described herein, may be built falls within the spirit and scope of the present disclosure.

In general, a field-effect transistor (FET), e.g., a metal oxide semiconductor (MOS) FET (MOSFET), is a three-terminal device that includes source, drain, and gate terminals and uses electric field to control current flowing through the device. A FET typically includes a channel material, a source region and a drain region provided in the channel material, and a gate stack that includes a gate electrode material, alternatively referred to as a “work function” material, provided over a portion of the channel material between the source and the drain regions, and, optionally, also includes a gate dielectric material between the gate electrode material and the channel material. In this example, the transistor 100 includes a pyroelectric material as the gate dielectric material between the gate electrode material and the channel material.

The general structure of an example of the transistor 100 is shown in FIG. 1, which shows the channel material 102, S/D regions 104 (shown as a first S/D region 104-1, e.g., a source region, and a second S/D region 104-2, e.g., a drain region), contacts 106 to the S/D regions (shown as a first S/D contact 106-1, providing electrical contact to the first S/D region 104-1, and a second S/D contact 106-2, providing electrical contact to the second S/D region 104-2), and a gate stack 108, which includes at least a gate electrode 110 and the pyroelectric material 112, which acts as a gate dielectric material.

The channel material 102 may include a monocrystalline semiconductor, such as silicon (Si) or germanium (Ge). In some embodiments, the channel material 102 may include a compound semiconductor with a first sub-lattice of at least one element from group III of the periodic table (e.g., Al, Ga, In), and a second sub-lattice of at least one element of group V of the periodic table (e.g., P, As, Sb). For some embodiments, the channel material 102 may include a III-V material having a high electron mobility, such as, but not limited to InGaAs, InP, InSb, and InAs. For some such embodiments, the channel material 102 may be a ternary III-V alloy, such as InGaAs, GaAsSb, InAsP, or InPSb. For some InₓGa₁₋ₓAs embodiments, the In content (x) may be between 0.6 and 0.9, and may advantageously be at least 0.7 (e.g., In_{0.7}Ga_{0.3}As). For other embodiments, one or more of the semiconductor materials may be a group IV material having a high hole mobility, such as, but not limited to Ge or a Ge-rich SiGe alloy. For some example embodiments, the channel material 102 may have a Ge content between 0.6 and 0.9, and may be at least 0.7.

In some embodiments, the channel material 102 may be a thin-film material, such as a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the channel material 102 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus. Suitable dopants for the channel material 102 may include gallium, indium, aluminum, fluorine, boron, phosphorus, arsenic, nitrogen, tantalum, tungsten, magnesium, etc.

As shown in FIG. 1, a first and a second S/D regions 104-1, 104-2 (together referred to as “S/D regions 104”) may be included on either side of the gate stack 108, thus realizing a transistor. As is known in the art, source and drain regions (also sometimes interchangeably referred to as “diffusion regions”) are formed for the gate stack of a FET. In some embodiments, the S/D regions 104 of the transistor 100 may be regions of doped semiconductors, e.g. regions of the channel material 102 (e.g., of the channel portion 114) doped with a suitable dopant to a suitable dopant concentration, so as to supply charge carriers for the transistor channel. In some embodiments, the S/D regions 104 may be highly doped, e.g. with dopant concentrations of about 1·10²¹ cm⁻³, in order to advantageously form Ohmic contacts with the respective S/D contacts 106, although, in other embodiments, these regions may also have lower dopant concentrations and may form Schottky contacts in some implementations. Irrespective of the exact doping levels, the S/D regions 104 may be the regions having dopant concentration higher than in other regions, e.g. higher than a dopant concentration in a region of the channel material 102 between the first S/D region 104-1 and the second S/D region 104-2, and, therefore, may be referred to as “highly doped” (HD) regions. In some embodiments, the S/D regions 104 may generally be formed using either an implantation/diffusion process or an etching/deposition process. In the former process, dopants such as boron, aluminum, antimony, phosphorous, or arsenic may be ion-implanted into the one or more semiconductor materials of the upper portion of the channel material 102 to form the S/D regions 104. An annealing process that activates the dopants and causes them to diffuse further into the channel material 102 may follow the ion implantation process. In the latter process, the one or more semiconductor materials of the channel material 102 may first be etched to form recesses at the locations for the future S/D regions. An epitaxial deposition process may then be carried out to fill the recesses with material (which may include a combination of different materials) that is used to fabricate the S/D regions 104. In some implementations, the S/D regions 104 may be fabricated using a silicon alloy such as silicon germanium or silicon carbide. In some implementations, the epitaxially deposited silicon alloy may be doped in situ with dopants such as boron, arsenic, or phosphorous. In further embodiments, the S/D regions 104 may be formed using one or more alternate semiconductor materials such as germanium or a group III-V material or alloy. Although FIG. 1 illustrates the first and second S/D regions 104 with a single pattern, suggesting that the material composition of the first and second S/D regions 104 is the same, this may not be the case in some other embodiments of the transistor 100. Thus, in some embodiments, the material composition of the first S/D region 104-1 may be different from the material composition of the second S/D region 104-2.

As further shown in FIG. 1, S/D contacts 106-1 and 106-2 (together referred to as “S/D contacts 106”), formed of one or more electrically conductive materials, may be used for providing electrical connectivity to the S/D regions 104-1 and 104-2, respectively. In various embodiments, one or more layers of metal and/or metal alloys may be used to form the S/D contacts 106. For example, the electrically conductive materials of the S/D contacts 106 may include one or more metals or metal alloys, with materials such as copper, ruthenium, palladium, platinum, cobalt, nickel, hafnium, zirconium, titanium, tantalum, and aluminum, tantalum nitride, tungsten, doped silicon, doped germanium, or alloys and mixtures of any of these. In some embodiments, the S/D contacts 106 may include one or more electrically conductive alloys, oxides, or carbides of one or more metals. In some embodiments, the S/D contacts 106 may include a doped semiconductor, such as silicon or another semiconductor doped with an N-type dopant or a P-type dopant. Metals may provide higher conductivity, while doped semiconductors may be easier to pattern during fabrication. Although FIG. 1 illustrates the first and second S/D contacts 106 with a single pattern, suggesting that the material composition of the first and second S/D contacts 106 is the same, this may not be the case in some other embodiments of the transistor 100. Thus, in some embodiments, the material composition of the first S/D contact 106-1 may be different from the material composition of the second S/D contact 106-2.

Turning to the gate stack 108, the gate electrode 110 may include at least one P-type work function metal or N-type work function metal, depending on whether the transistor 100 is a PMOS transistor or an NMOS transistor. For a PMOS transistor, metals that may be used for the gate electrode 110 may include, but are not limited to, ruthenium, palladium, platinum, cobalt, nickel, and conductive metal oxides (e.g., ruthenium oxide). For an NMOS transistor, metals that may be used for the gate electrode 110 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode 110 may include a stack of two or more metal layers, where one or more metal layers are WF metal layers and at least one metal layer is a fill metal layer. Further metal layers may be included for other purposes, such as to act as a diffusion barrier layer.

The pyroelectric material 112 is between the gate electrode 110 and the channel portion 114 of the channel material 102. For example, the pyroelectric material 112 may at least laterally surround the channel portion 114, and the gate electrode 110 may laterally surround the pyroelectric material 112 such that the pyroelectric material 112 is disposed between the pyroelectric material 112 and the channel material 102. In some embodiments, the pyroelectric material 112 may have a thickness that is less than 10 nanometers, or less than 5 nanometers, e.g., between 0.5 nanometers and 5 nanometers, including all values and ranges therein, e.g., between 1 and 3 nanometers, or between 3 and 5 nanometers.

The pyroelectric material 112 is a crystalline material in which the crystal structure is temperature-dependent. The pyroelectric material 112 may have alternatively an orthorhombic or tetragonal crystal structure. Example crystal structures of pyroelectric materials are illustrated in FIGS. 2A-2C, described below. Applying heat pulse causes the pyroelectric material 112 to switch between the two configurations. For example, a higher temperature pulse may cause the pyroelectric layer to have an orthorhombic crystal structure, and a lower temperature pulse may cause the pyroelectric layer to switch to a tetragonal crystal structure.

The higher temperature pulse may heat the transistor 100 (and, specifically, the pyroelectric material 112 of the transistor 100) to a temperature over 500° C., over 550° C., over 600° C., over 700° C., between 500° C. and 700° C., between 550° C. and 650° C., or to some other range. The lower temperature pulse may heat the pyroelectric material 112 of the transistor 100 to a temperature that is less than the higher temperature pulse, e.g., a temperature between 300° C. and 600° C. or a range therein, e.g., between 300° C. and 600° C., between 350° C. and 500° C., below 400° C., etc. The lower temperature pulse may be at least 200° C., at least 150° C., at least 100° C., or at least 50° C. less than higher temperature pulse. For example, a difference between the higher temperature pulse and lower temperature pulse may be between 50° C. and 250° C., between 100° C. and 200° C., or within some other range. The pulse durations may be different, e.g., the lower-temperature pulse may be at least twice as long as the higher-temperature pulse, at least three times as long, at least four times as long, or at least five times as long. Each pulse duration may be between, for example, one microsecond and one second. For example, the higher temperature pulse may have a duration of 5 milliseconds, and the lower temperature pulse may have a duration of 15 milliseconds. The pulse temperatures and durations may be selected based on the pyroelectric material 112.

The pyroelectric material 112 may specifically be a pyroelectric insulator. In some embodiments, the pyroelectric material 218 may include hafnium oxide (which includes hafnium and oxygen) and/or zirconium oxide (which includes zirconium and oxygen). Hafnium oxide or zirconium oxide may optionally be doped with vacancies (i.e., vacancies in the hafnium or zirconium positions) and/or one or more of zirconium, hafnium, silicon, aluminum, tantalum, germanium, gallium, titanium, or another dopant. Other pyroelectric materials include PZT (lead zirconium titanate, which includes lead, zirconium, titanium, and oxygen); BTO (barium titanate, which includes barium, titanium, and oxygen); and tantalum oxide (which includes tantalum and oxygen). In other embodiments, different pyroelectric oxides or nitrides not specifically mentioned above may be used as the pyroelectric material 218. In some embodiments, a mixture of different materials may be included in the pyroelectric material 218, e.g., hafnium oxide mixed with one or more of zirconium oxide, silicon oxide, scandium oxide, aluminum oxide, gallium nitride, indium nitride, indium oxide, tantalum oxide, aluminum nitride, aluminum scandium nitride, etc.

The crystal structure may be highly consistent across the pyroelectric material 112. For example, the pyroelectric material 112 may also be capable of forming different crystal structures, e.g., cubic or hexagonal structures, which are not suitable for use as a memory device. The pyroelectric material 112 (e.g., one or more cross-sections through the pyroelectric material 218) may include a minimal amount, e.g., less than 10%, less than 5%, less than 2%, less than 1%, less than 0.5%, of crystals in an undesired configuration, e.g., cubic or hexagonal. Said another way, in a cross-section through the pyroelectric material 112, at least 90%, at least 95%, at least 98%, at least 99%, or at least 99.5% of the pyroelectric material 112 may have an orthorhombic or tetragonal crystal structure. This differs from a typical ferroelectric material, which typically includes a higher percentage of the material in a cubic or hexagonal structure, e.g., between 5% and 50% of a ferroelectric material may have a cubic or hexagonal crystal structure.

The desired crystal structures (orthorhombic and tetragonal) may be achieved by controlling deposition temperature; a higher deposition temperature (e.g., at least 250° C. or at least 300° C.) may provide the desired crystal structure. The deposition temperature may be compatible for back-end processing, e.g., the deposition temperature may be in a range of 250-400° C. In other embodiments, if the pyroelectric material 218 is deposited during front-end processing, a higher deposition temperature may be used (e.g., above 400° C.). Whether the pyroelectric material 112 is orthorhombic or tetragonal at a given time depends on a temperature applied to, as described above.

The transistor 100 may additionally include one or more additional materials not specifically shown in FIG. 1. For example, the transistor 100 may include an additional dielectric layer above or below the pyroelectric material 112, e.g., between the pyroelectric material 112 and the gate electrode 110 and/or between the pyroelectric material 112 and the channel material 102.

In some embodiments, the gate stack 108 may be surrounded by a dielectric spacer, not specifically shown in FIG. 1. The dielectric spacer may be configured to provide separation between the gate stacks 108 of different transistors which may be provided adjacent to one another (e.g., different transistors provided along a single fin if the transistors 100 are FinFETs), as well as between the gate stack 108 and one of the S/D contacts 106 that is disposed on the same side as the gate stack 108. Such a dielectric spacer may include one or more low-k dielectric materials. Examples of the low-k dielectric materials that may be used as the dielectric spacer (or in other dielectric materials described herein) include, but are not limited to, silicon dioxide, carbon-doped oxide, silicon nitride, fused silica glass (FSG), and organosilicates such as silsesquioxane, siloxane, and organosilicate glass. Other examples of low-k dielectric materials include organic polymers such as polyimide, polynorbornenes, benzocyclobutene, perfluorocyclobutane, or polytetrafluoroethylene (PTFE). Still other examples of low-k dielectric materials that may be used as the dielectric spacer include silicon-based polymeric dielectrics such as hydrogen silsesquioxane (HSQ) and methylsilsesquioxane (MSQ). Other examples of low-k materials that may be used in a dielectric spacer include various porous dielectric materials, such as for example porous silicon dioxide or porous carbon-doped silicon dioxide, where large voids or pores are created in a dielectric in order to reduce the overall dielectric constant of the layer, since voids can have a dielectric constant of nearly 1.

In this example, both of the S/D contacts 106 are on the same side of the transistor, e.g., a front side of the transistor. The gate stack 108 is also on the front side of the transistor. In other embodiments, one or more of the S/D contacts 106, and/or the gate stack 108, are on a back side of the transistor, referred to as the back side.

The transistor 100 may be implemented using any suitable transistor architecture, e.g. planar or non-planar architectures. In some embodiments, the transistor 100 is a TFT, as described above. In some embodiments, the gate stack 108 may be recessed relative to the S/D contacts 106, so that a height of the channel material 102 under the gate stack 108 is less than a height of the channel material 102 under the S/D regions 104, or a height of the channel material 102 under the gate stack 108 is less than a height of the channel material 102 under the S/D regions 104 plus the height of the S/D regions 104.

In other examples, the transistor 100 may be implemented as a non-planar transistor, such as fin-shaped field-effect transistor, referred to as a FinFET, or a gate-all-around (GAA) transistor. GAA transistors, also referred to as surrounding-gate transistors, have a gate material that surrounds a channel region on all sides. GAA transistors may be nanoribbon-based or nanowire-based. Compared to planar transistors, non-planar transistors can provide improved control over current flow, reduced leakage, and enhanced performance, making it a key technology for smaller, faster, and more energy-efficient electronic devices.

FinFETs are transistors having a non-planar architecture where a fin, formed of one or more semiconductor materials (e.g., any of the channel materials 102), extends away from a base (where the term “base” refers to any suitable support structure on which a transistor may be built, e.g., a substrate as described above). A portion of the fin that is closest to the base may be enclosed by an insulator material. Such an insulator material, typically an oxide, is commonly referred to as a “shallow trench isolation” (STI), and the portion of the fin enclosed by the STI is typically referred to as a “subfin portion” or simply a “subfin.” A gate stack 108 that includes at least a layer of a gate electrode material (e.g., the gate electrode 110) and, in this case, a layer of the pyroelectric material 112 is provided over the top and sides of the remaining upper portion of the fin (i.e., the portion above and not enclosed by the STI), thus wrapping around the upper-most portion of the fin. The portion of the fin over which the gate stack wraps around is typically referred to as a “channel portion” of the fin (e.g., the channel portion 114) because this is where, during operation of the transistor, a conductive channel forms, and is a part of an active region of the fin. The S/D regions 104 are provided on the opposite sides of the gate stack, forming the source and drain terminals of a transistor. FinFETs may be implemented as “tri-gate transistors,” where the name “tri-gate” originates from the fact that, in use, such transistors may form conducting channels on three “sides” of the fin.

In a GAA transistor or nanoribbon-based transistor (referred to generally as a nanoribbon transistor), the gate stack 108 that includes a stack of one or more gate electrode materials (e.g., the gate electrode 110) and the pyroelectric material 112 may be provided around one or more elongated semiconductor structures called “nanoribbons”, forming a gate on all sides of the nanoribbon or nanoribbons. The nanoribbons are formed from the channel material 102. A portion of a nanoribbon around which the gate stack wraps around is referred to as a “channel” or a “channel portion.” A source region and a drain region (e.g., the S/D regions 104) are provided on the opposite ends of the nanoribbons, on either side of the gate stack 108, forming, respectively, a source and a drain of such a transistor.

### Example Crystal Structures of Pyroelectric Materials

FIG. 2A-2C illustrate three example crystal structures of pyroelectric materials, according to some embodiments of the present disclosure. FIG. 2A illustrates a cubic crystal structure. In this structure, atoms are represented as dots, e.g., 200a and 200b. The atoms are positioned the corners of a cube, and edges representing lengths between various pairs of atoms are shown. For example, the edge 205 extends between the atoms 200a and 200b. In general, a crystal structure of a pyroelectric material can be described by six lattice parameters: three representing the edge lengths, and three representing the angles between the cell edges. In the cubic, tetragonal, and orthorhombic structures described herein, all of the angles are 90°. In a cubic structure, all of the edge lengths are equal. For example, in the reference coordinate system shown in FIG. 2A, the edge lengths in the x-direction, the y-direction, and the z-direction all have a length a. Thus, all six sides of the depicted crystal form a square.

If the cubic structure shown in FIG. 2A is the prevailing crystal structure, or if the cubic structure makes up more than a minimum amount of material (e.g., if more than 2%, more than 3%, or more than 5% of the crystals have a cubic structure), the material does not have the pyroelectric characteristics described above. On the other hand, the cubic crystal structure shown in FIG. 2A is prevalent (e.g., at least 2%, at least 3%, or at least 5% of the crystals have a cubic structure) in ferroelectric, non-pyroelectric materials.

A pyroelectric material used in the transistor 100 and other transistors with pyroelectric layers described herein may alternate between the crystal structures represented in FIG. 2B and FIG. 2C. The different structures may be associated with different degrees of polarizations, and different dielectric constants, leading to different threshold voltages, as described above.

FIG. 2B illustrates a tetragonal crystal structure. As in FIG. 2A, atoms are represented as dots, here represented as dots 210 (e.g., dots 210a and 210b), which are positioned at the corners of the crystal, and edges representing lengths between certain pairs of atoms are shown. As noted above, in the tetragonal structure, all of the angles are 90°. In a tetragonal structure, two of the edge lengths are equal, and one of the edge lengths is different. For example, in the reference coordinate system shown in FIG. 2B, the edge lengths in the x-direction and the y-direction both have a length a. Thus, the base and top of the depicted crystal each form a square. The edge length in the z-direction is c, which is different from the length a. The tetragonal crystal has the shape of a rectangular prism with a square base.

FIG. 2C illustrates an orthorhombic crystal structure. Atoms in this crystal structure, represented as dots 220 (e.g., dots 220a and 220b), are positioned at the corners of the crystal, and edges representing lengths between certain pairs of atoms are shown. In an orthorhombic crystal structure, the angles between the cell edges are all 90°, but the edge lengths are all different. For example, in the reference coordinate system shown in FIG. 2C, the edge length in the x-direction is a, the edge length in the y-direction is b, and the edge length in the z-direction is c, where a≠b≠c.

### Example Transistor Regions with Independent Threshold Voltage Control

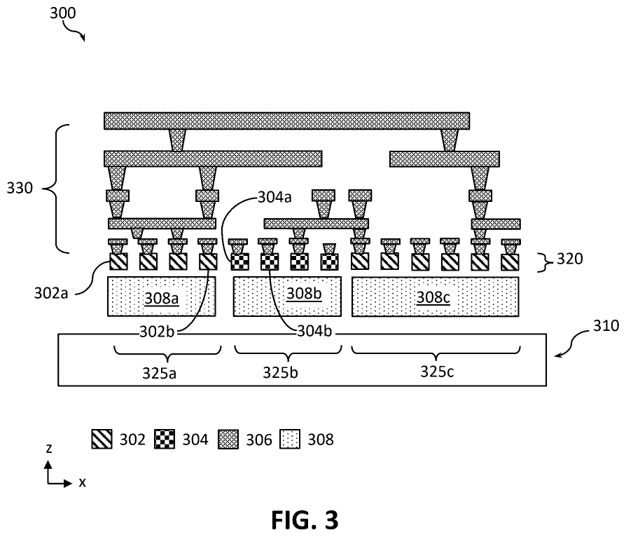

FIG. 3 is a cross-section of an example IC device 300 that includes transistors with different transistor regions, according to some embodiments of the present disclosure. FIG. 3 includes a device layer 320, which includes transistors having a pyroelectric layer. While a single device layer 320 is illustrated in FIG. 3, the IC device 300 may include multiple device layers at different heights in the z-direction. Each of the transistors, such as transistor 302a and transistor 304a, is abstracted as a box. Two different patterns represent transistors with different crystal structures in their pyroelectric layers. For example, the transistors 302, which include transistors 302a and 302b, may have a layer of the pyroelectric material 112 arranged in an orthorhombic crystal structure, and the transistors 304, which include transistors 304a and 304b, may have a layer of the pyroelectric material 112 arranged in a tetragonal crystal structure. The transistors in the device layer 320 are arranged into regions 325, where different regions are located at different positions along the x-axis in the coordinate system shown. Transistors 302a and 302b are in the region 325a, and the transistors 304a and 304b are in the region 325b. In the example shown, the transistors in the regions 325a and 325c are transistors 302, e.g., transistors with a pyroelectric layer arranged in an orthorhombic crystal structure; transistors in the region 325b are transistors 304, e.g., transistors with a pyroelectric layer arranged in a tetragonal crystal structure. More generally, transistors in the region 325b have a pyroelectric material with a different crystal structure from the transistors in the regions 325a and 325c.

The regions 325a, 325b, and 325c are formed over heating elements 308a, 308b, and 308c, respectively. The heating elements 308 can apply heat pulses to the transistors in the respective regions 325. For example, the heating element 308a may have applied a first heat pulse (e.g., with a first temperature and duration) to the region 325a, causing the transistors in the region 325a to have their pyroelectric layers arranged in an orthorhombic crystal structure. The heating element 308a may apply a second heat pulse (e.g., with a second temperature and duration) to the region 325a, which causes the transistors in the region 325a to transform into the transistors 304, e.g., transistors with a pyroelectric layer arranged in a tetragonal crystal structure. As described above, using a heating element 308 to change the crystal structure of the adjacent region 325 causes transistors within the region to have a different threshold voltage. The heating elements 308 may be, for example, tungsten microheaters or other microheaters suitable for inclusion in an IC chip or IC package, and capable of delivering the heat pulses described herein.

Interconnects 306 are arranged in layers over the device layer 320 to form a metallization stack 330. The interconnects 306 form conductive pathways to route power, ground, and/or signals to/from various components of the device layer 320. The transistors 302 and 304 are coupled to the interconnects 306, e.g., through conductive contacts such as the S/D contacts 106 shown in FIG. 1. Each layer in the metallization stack 330 may include a dielectric material (not specifically shown), where the dielectric material is formed in multiple layers, as known in the art. The interconnects 306 may include one or more conductive traces and conductive vias, providing one or more conductive pathways through the insulating materials. The interconnects 306 may be formed from appropriate conductive material, such as copper, silver, nickel, gold, aluminum, or other metals or alloys, for example. The conductive pathways may be connected to one another in any suitable manner. While all of the interconnects 306 in FIG. 3 are illustrated as being formed from the same material, in other embodiments, different materials may be used, e.g., different layers of the metallization stack 330 may include different materials. Although FIG. 3 illustrates a specific number and arrangement of conductive pathways formed by the interconnects 306, these are simply illustrative, and any suitable number and arrangement may be used.

In this example, a support structure 310 is under the heating elements 308. The support structure 310 may in turn be coupled to other external components, e.g., for input and output of signals, and input of power to the IC device 300. For example, connections may extend through the support structure 310 to the heating elements 308 to provide power to the heating elements 308. As another example, power and/or signal connections may extend through the support structure 310, between heating elements 308, and to the device layer 320, to provide power and/or signals to the transistors 302 and 304 and/or to the metallization stack 330. The IC device 300 may have other alternative configurations to route electrical signals from the device layer 320 and metallization stack 330 and out of the IC device 300.

In this example, the interconnects 306 are illustrated as being over a front side of the device layer 320, and the heating elements 308 are illustrated as being under a back side of the device layer 320. In other embodiments, the heating elements 308 may be formed over a front side of the device layer 320, e.g., within the metallization stack 330, or between the metallization stack 330 and the device layer 320. Alternatively, the metallization stack 330 may be formed under the back side of the device layer 320, with the heating elements 308 on the opposite side (i.e., over a front side of the device layer 320), within the back side metallization stack, or between the back side metallization stack and the device layer 320. In still other embodiments, heating elements 308 may be at least partially within the device layer 320, e.g., with each heating element 308 within a particular region 325 of transistors.

While not specifically shown, the transistors 302 and 304, heating elements 308, and interconnects 306 may be surrounded by one or more insulating materials, such as silicon dioxide, silicon nitride, oxynitride, polyimide materials, glass reinforced epoxy matrix materials, or a low-k or ultra-low-k dielectric (e.g., carbon-doped dielectrics, fluorine-doped dielectrics, porous dielectrics, organic polymeric dielectrics, photo-imageable dielectrics, and/or benzocyclobutene-based polymers). In some embodiments, the insulating material 312 may include a semiconductor material, such as silicon, germanium, or a III-V material (e.g., gallium nitride), and one or more additional materials. For example, the insulating material may include silicon oxide or silicon nitride. An insulating material in the device layer 320 may be different from insulating materials around the interconnects 306 and/or different from insulating materials around the heating elements 308.

One or more such insulating materials may be between adjacent heating elements 308, and/or between adjacent regions 325 of the device layer 320. One or more insulating layers or buffer may be between the heating elements 308 and device layer 320, as long as sufficient heat from the heating element 308 reaches the adjacent region 325 of the device layer 320 to deliver the heat pulse, i.e., to heat the transistors 302 or 304 to the desired temperature to change the crystal structure of the pyroelectric material 112.

### Example Transistors with Different Pyroelectric Crystal Structures

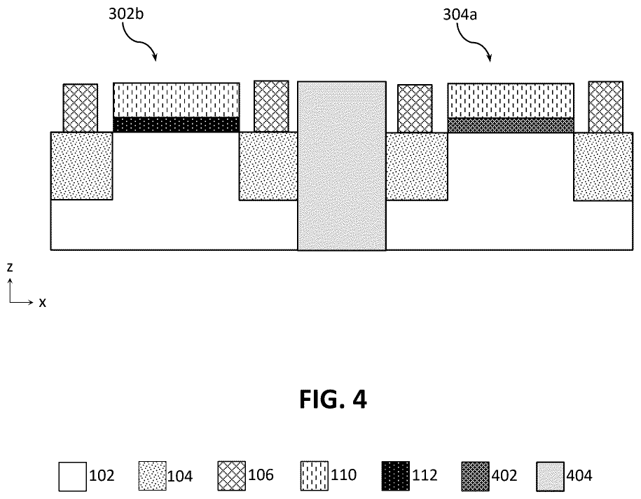

FIG. 4 is a cross-section of two transistors with pyroelectric layers with different crystal structures, according to some embodiments of the present disclosure. Specifically, FIG. 4 illustrates the transistors 302b and 304a of FIG. 3 in greater detail. The transistors 302b and 304a are in different regions (regions 325a and 325b, respectively) of the device layer 320. The transistors 302b and 304a are separated by a dielectric region 404, which may be formed from any of the dielectric materials described above. The dielectric region 404 electrically isolates the transistors 302b and 304a. In addition, the dielectric region 404 may, at least in part, thermally isolate the transistor 302b from the heating element 308b, and thermally isolate the transistor 304a from the heating element 308a.

Each of the transistors 302b and 304a is similar to the transistor 100, described above. Each transistor 302b and 304a includes a channel material 102, two S/D regions 104, two S/D contacts 106, and a gate stack that includes the gate electrode 110. Each transistor 302b and 304b includes a pyroelectric layer between the channel material 102 and the gate electrode 110. In this example, the transistor 302b includes the pyroelectric material 112, which is the pyroelectric material 112 having a particular crystal configuration. The transistor 304a includes a pyroelectric material 402. The pyroelectric material 402 may be similar to the pyroelectric material 112 (e.g., have the same chemical composition), however, the pyroelectric material 402 has a different crystal configuration from the pyroelectric material 112. For example, the pyroelectric material 402 has a tetragonal configuration, and the pyroelectric material 112 has an orthorhombic configuration, or vice versa.

The crystal configurations may be changed using the heating elements 308, so that, at different times, the pyroelectric layers of the transistors 302b and 304a may have the same crystal configuration (e.g., both orthorhombic or both tetragonal). The different crystal configurations may remain in the absence of a heating element. For example, if a device including the transistors 302b and 304a is removed from a power source, the pyroelectric layers of the transistors 302b and 304a may have the crystal configuration induced by the most recent heat pulse. Thus, in a cross-section of a device, different crystal structures in the gate dielectric layer of a pair of transistors (e.g., the transistors 302b and 304a) may be observed.

Method for Operating Transistor with Pyroelectric Layer

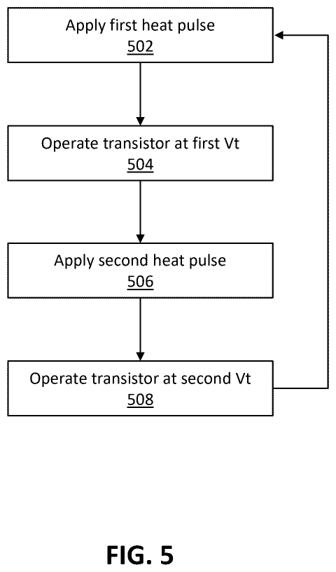

FIG. 5 is a flowchart illustrating a method for operating a transistor with a pyroelectric layer, according to some embodiments of the present disclosure. At 502, a heating element (e.g., the heating element 308a) applies a first heat pulse. The first heat pulse may have a first temperature and a first duration, e.g., any of the temperatures and durations for the higher temperature heat pulse described with respect to FIG. 1.

At 504, the IC device operates the transistor at a first threshold voltage, e.g., the threshold voltage associated with the orthogonal crystal structure induced by the high temperature heat pulse. The IC device may apply a gate-source differential that is at least the first threshold voltage to turn on the transistor.

At 506, the heating element (e.g., the heating element 308a) applies a second heat pulse. The second heat pulse may have a second temperature and a second duration, e.g., any of the temperatures and durations for the lower temperature heat pulse described with respect to FIG. 1.

At 508, the IC device operates the transistor at a second threshold voltage, e.g., the threshold voltage associated with the tetragonal crystal structure induced by the lower temperature heat pulse. The IC device may apply a gate-source differential that is at least the second threshold voltage to turn on the transistor.

### Example devices

The transistors with pyroelectric layers disclosed herein may be included in any suitable electronic device. FIGS. 6-9 illustrate various examples of apparatuses that may include the one or more transistors disclosed herein.

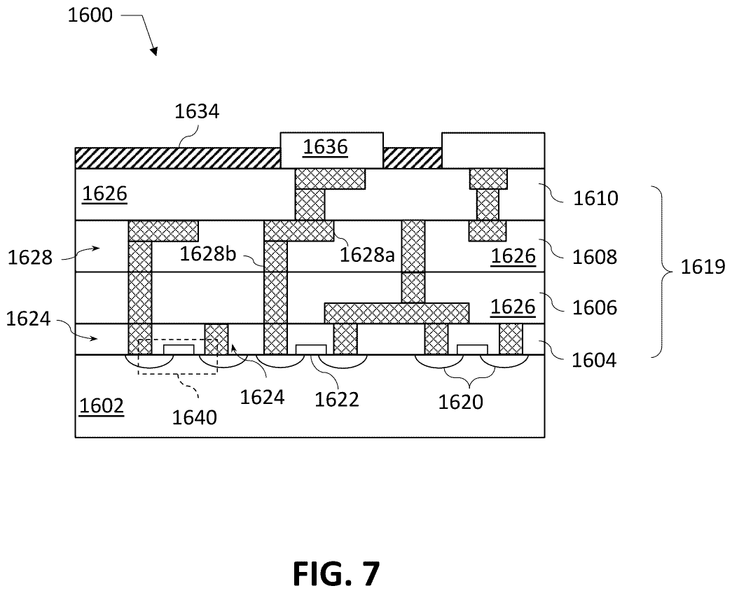

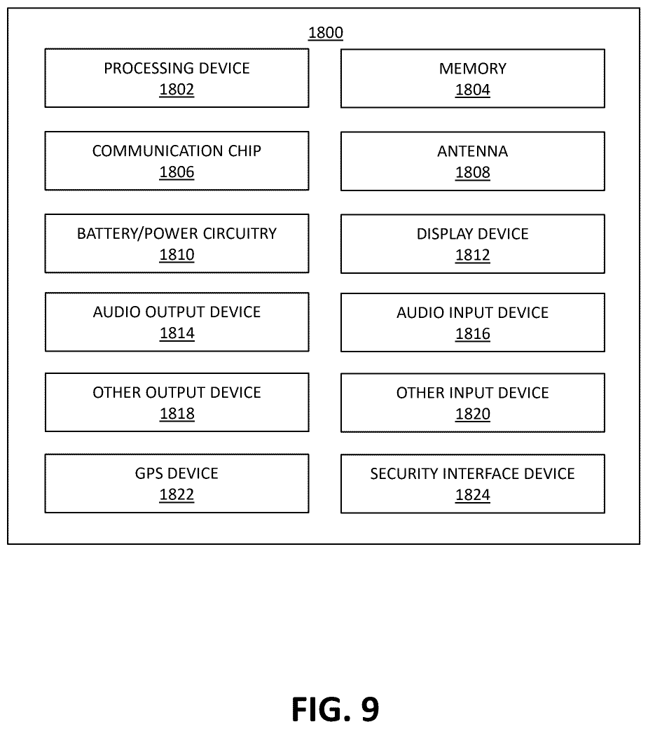

FIGS. 6A and 6B are top views of a wafer and dies that include one or more IC structures including one or more transistors with pyroelectric layers in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC structure (e.g., the IC structures as shown in any of FIGS. 1-5, or any further embodiments of the IC structures described herein). After the fabrication of the semiconductor product is complete (e.g., after manufacture of one or more IC structures with one or more of the transistors as described herein, included in a particular electronic component, e.g., in a transistor or in a memory device), the wafer 1500 may undergo a singulation process in which each of the dies 1502 is separated from one another to provide discrete “chips” of the semiconductor product. In particular, devices that include one or more of the transistors as disclosed herein may take the form of the wafer 1500 (e.g., not singulated) or the form of the die 1502 (e.g., singulated). The die 1502 may include one or more transistors (e.g., one or more of the transistors 1640 of FIG. 7, discussed below) and/or supporting circuitry to route electrical signals to the transistors, as well as any other IC components (e.g., one or more of the non-planar transistors described herein). In some embodiments, the wafer 1500 or the die 1502 may include a memory device (e.g., an SRAM device), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 9) or other logic that is configured to store information in the memory devices or execute instructions stored in the memory array.

FIG. 7 is a cross-sectional side view of an IC device 1600 that may include one or more transistors with pyroelectric layers in accordance with any of the embodiments disclosed herein. The IC device 1600 may be formed on a substrate 1602 (e.g., the wafer 1500 of FIG. 6A) and may be included in a die (e.g., the die 1502 of FIG. 6B). The substrate 1602 may be any substrate as described herein. The substrate 1602 may be part of a singulated die (e.g., the dies 1502 of FIG. 6B) or a wafer (e.g., the wafer 1500 of FIG. 6A).

The IC device 1600 may include one or more device layers 1604 disposed on the substrate 1602. The device layer 1604 may include features of one or more transistors 1640 (e.g., metal-oxide-semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 7 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate electrode layer and a gate dielectric layer.

The gate electrode layer may be formed on the gate interconnect support layer and may consist of at least one P-type workfunction metal or N-type workfunction metal, depending on whether the transistor is to be a PMOS or an NMOS transistor, respectively. In some implementations, the gate electrode layer may consist of a stack of two or more metal layers, where one or more metal layers are workfunction metal layers and at least one metal layer is a fill metal layer. Further metal layers may be included for other purposes, such as a barrier layer or/and an adhesion layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 electron Volts (eV) and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, aluminum carbide, tungsten, tungsten carbide. An N-type metal layer will enable the formation of an NMOS gate electrode with a workfunction that is between about 3.9 eV and about 4.2 eV.

In some embodiments, when viewed as a cross-section of the transistor 1640 along the source-channel-drain direction, the gate electrode may be formed as a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may be implemented as a combination of U-shaped structures and planar, non-U-shaped structures. For example, the gate electrode may be implemented as one or more U-shaped metal layers formed atop one or more planar, non-U-shaped layers. In some embodiments, the gate electrode may consist of a V-shaped structure (e.g., when a fin of a FinFET transistor does not have a “flat” upper surface, but instead has a rounded peak).

Generally, the gate dielectric layer of a transistor 1640 may include one layer or a stack of layers, and the one or more layers may include silicon oxide, silicon dioxide, and/or a high-k dielectric material. The high-k dielectric material included in the gate dielectric layer of the transistor 1640 may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The IC device 1600 may include one or more transistors with pyroelectric layers at any suitable location in the IC device 1600.

The S/D regions 1620 may be formed within the substrate 1602 adjacent to the gate 1622 of each transistor 1640, using any suitable processes known in the art. For example, the S/D regions 1620 may be formed using either an implantation/diffusion process or a deposition process. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion implantation process. In the latter process, an epitaxial deposition process may provide material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620. In some embodiments, an etch process may be performed before the epitaxial deposition to create recesses in the substrate 1602 in which the material for the S/D regions 1620 is deposited.

Electrical signals, such as power and/or input/output (I/O) signals, may be routed to and/or from the transistors 1640 of the device layer 1604 through one or more interconnect layers disposed on the device layer 1604 (illustrated in FIG. 7 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form an ILD stack 1619 of the IC device 1600.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 7). Although a particular number of interconnect layers 1606-1610 is depicted in FIG. 7, embodiments of the present disclosure include IC devices having more or fewer interconnect layers than depicted.

In some embodiments, the interconnect structures 1628 may include trench contact structures 1628a (sometimes referred to as “lines”) and/or via structures 1628b (sometimes referred to as “holes”) filled with an electrically conductive material such as a metal. The trench contact structures 1628a may be arranged to route electrical signals in a direction of a plane that is substantially parallel with a surface of the substrate 1602 upon which the device layer 1604 is formed. For example, the trench contact structures 1628a may route electrical signals in a direction in and out of the page from the perspective of FIG. 7. The via structures 1628b may be arranged to route electrical signals in a direction of a plane that is substantially perpendicular to the surface of the substrate 1602 upon which the device layer 1604 is formed. In some embodiments, the via structures 1628b may electrically couple trench contact structures 1628a of different interconnect layers 1606-1610 together.

The interconnect layers 1606-1610 may include a dielectric material 1626 disposed between the interconnect structures 1628, as shown in FIG. 7. The dielectric material 1626 may take the form of any of the embodiments of the dielectric material provided between the interconnects of the IC structures disclosed herein.

In some embodiments, the dielectric material 1626 disposed between the interconnect structures 1628 in different ones of the interconnect layers 1606-1610 may have different compositions. In other embodiments, the composition of the dielectric material 1626 between different interconnect layers 1606-1610 may be the same.

A first interconnect layer 1606 (referred to as Metal 1 or “M1”) may be formed directly on the device layer 1604. In some embodiments, the first interconnect layer 1606 may include trench contact structures 1628a and/or via structures 1628b, as shown. The trench contact structures 1628a of the first interconnect layer 1606 may be coupled with contacts (e.g., the S/D contacts 1624) of the device layer 1604.

A second interconnect layer 1608 (referred to as Metal 2 or “M2”) may be formed directly on the first interconnect layer 1606. In some embodiments, the second interconnect layer 1608 may include via structures 1628b to couple the trench contact structures 1628a of the second interconnect layer 1608 with the trench contact structures 1628a of the first interconnect layer 1606. Although the trench contact structures 1628a and the via structures 1628b are structurally delineated with a line within each interconnect layer (e.g., within the second interconnect layer 1608) for the sake of clarity, the trench contact structures 1628a and the via structures 1628b may be structurally and/or materially contiguous (e.g., simultaneously filled during a dual-damascene process) in some embodiments.

A third interconnect layer 1610 (referred to as Metal 3 or “M3”) (and additional interconnect layers, as desired) may be formed in succession on the second interconnect layer 1608 according to similar techniques and configurations described in connection with the second interconnect layer 1608 or the first interconnect layer 1606.

The IC device 1600 may include a solder resist material 1634 (e.g., polyimide or similar material) and one or more bond pads 1636 formed on the interconnect layers 1606-1610. The bond pads 1636 may be electrically coupled with the interconnect structures 1628 and configured to route the electrical signals of the transistor(s) 1640 to other external devices. For example, solder bonds may be formed on the one or more bond pads 1636 to mechanically and/or electrically couple a chip including the IC device 1600 with another component (e.g., a circuit board). The IC device 1600 may have other alternative configurations to route the electrical signals from the interconnect layers 1606-1610 than depicted in other embodiments. For example, the bond pads 1636 may be replaced by or may further include other analogous features (e.g., posts) that route the electrical signals to external components.

FIG. 8 is a cross-sectional side view of an IC device assembly 1700 that may include components having or being associated with (e.g., being electrically connected by means of) one or more transistors with pyroelectric layers in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. In particular, any suitable ones of the components of the IC device assembly 1700 may include one or more of the non-planar transistors disclosed herein.

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 8 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702 and may include solder balls (as shown in FIG. 8), male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 8, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 6B), an IC device (e.g., the IC device 1600 of FIG. 7), or any other suitable component. In some embodiments, the IC package 1720 may include one or more transistors with pyroelectric layers, as described herein. Generally, the interposer 1704 may spread a connection to a wider pitch or reroute a connection to a different connection. For example, the interposer 1704 may couple the IC package 1720 (e.g., a die) to a ball grid array (BGA) of the coupling components 1716 for coupling to the circuit board 1702. In the embodiment illustrated in FIG. 8, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

The interposer 1704 may be formed of an epoxy resin, a fiberglass-reinforced epoxy resin, a ceramic material, or a polymer material such as polyimide. In some implementations, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 8 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 9 is a block diagram of an example computing device 1800 that may include one or more transistors with pyroelectric layers in accordance with any of the embodiments disclosed herein. For example, any suitable ones of the components of the computing device 1800 may include a die (e.g., the die 1502 (FIG. 6B)) having one or more transistors with pyroelectric layers. Any one or more of the components of the computing device 1800 may include, or be included in, an IC device 1600 (FIG. 7). Any one or more of the components of the computing device 1800 may include, or be included in, an IC device assembly 1700 (FIG. 8).

A number of components are illustrated in FIG. 9 as included in the computing device 1800, but any one or more of these components may be omitted or duplicated, as suitable for the application. In some embodiments, some or all of the components included in the computing device 1800 may be attached to one or more motherboards. In some embodiments, some or all of these components are fabricated onto a single system-on-a-chip (SoC) die.

Additionally, in various embodiments, the computing device 1800 may not include one or more of the components illustrated in FIG. 9, but the computing device 1800 may include interface circuitry for coupling to the one or more components. For example, the computing device 1800 may not include a display device 1812, but may include display device interface circuitry (e.g., a connector and driver circuitry) to which a display device 1812 may be coupled. In another set of examples, the computing device 1800 may not include an audio input device 1816 or an audio output device 1814, but may include audio input or output device interface circuitry (e.g., connectors and supporting circuitry) to which an audio input device 1816 or audio output device 1814 may be coupled.

The computing device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random access memory (eDRAM) or spin transfer torque magnetic random-access memory (STT-MRAM).

In some embodiments, the computing device 1800 may include a communication chip 1806 (e.g., one or more communication chips). For example, the communication chip 1806 may be configured for managing wireless communications for the transfer of data to and from the computing device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1806 may implement any of a number of wireless standards or protocols, including but not limited to Institute for Electrical and Electronic Engineers (IEEE) standards including Wi-Fi (IEEE 1402.11 family), IEEE 1402.18 standards (e.g., IEEE 1402.18-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.18 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.18 standards. The communication chip 1806 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1806 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1806 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1806 may operate in accordance with other wireless protocols in other embodiments. The computing device 1800 may include an antenna 1808 to facilitate wireless communications and/or to receive other wireless communications (such as AM or FM radio transmissions).

In some embodiments, the communication chip 1806 may manage wired communications, such as electrical, optical, or any other suitable communication protocols (e.g., the Ethernet). As noted above, the communication chip 1806 may include multiple communication chips. For instance, a first communication chip 1806 may be dedicated to shorter-range wireless communications such as Wi-Fi or Bluetooth, and a second communication chip 1806 may be dedicated to longer-range wireless communications such as GPS, EDGE, GPRS, CDMA, WiMAX, LTE, EV-DO, or others. In some embodiments, a first communication chip 1806 may be dedicated to wireless communications, and a second communication chip 1806 may be dedicated to wired communications.

The computing device 1800 may include a battery/power circuitry 1810. The battery/power circuitry 1810 may include one or more energy storage devices (e.g., batteries or capacitors) and/or circuitry for coupling components of the computing device 1800 to an energy source separate from the computing device 1800 (e.g., AC line power).

The computing device 1800 may include a display device 1812 (or corresponding interface circuitry, as discussed above). The display device 1812 may include any visual indicators, such as a heads-up display, a computer monitor, a projector, a touchscreen display, a liquid crystal display (LCD), a light-emitting diode display, or a flat panel display, for example.

The computing device 1800 may include an audio output device 1814 (or corresponding interface circuitry, as discussed above). The audio output device 1814 may include any device that generates an audible indicator, such as speakers, headsets, or earbuds, for example.

The computing device 1800 may include an audio input device 1816 (or corresponding interface circuitry, as discussed above). The audio input device 1816 may include any device that generates a signal representative of a sound, such as microphones, microphone arrays, or digital instruments (e.g., instruments having a musical instrument digital interface (MIDI) output).

The computing device 1800 may include another output device 1818 (or corresponding interface circuitry, as discussed above). Examples of the other output device 1818 may include an audio codec, a video codec, a printer, a wired or wireless transmitter for providing information to other devices, or an additional storage device.

The computing device 1800 may include another input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 1800 may include a global positioning system (GPS) device 1822 (or corresponding interface circuitry, as discussed above). The GPS device 1822 may be in communication with a satellite-based system and may receive a location of the computing device 1800, as known in the art.

The computing device 1800 may include a security interface device 1824. The security interface device 1824 may include any device that provides security features for the computing device 1800 or for any individual components therein (e.g., for the processing device 1802 or for the memory 1804). Examples of security features may include authorization, access to digital certificates, access to items in keychains, etc. Examples of the security interface device 1824 may include a software firewall, a hardware firewall, an antivirus, a content filtering device, or an intrusion detection device.

The computing device 1800 may have any desired form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 1800 may be any other electronic device that processes data.

### Select Examples

The following paragraphs provide various examples of the embodiments disclosed herein.

Example 1 provides a device including a first transistor including a first semiconductor region; a first conductive region; and a first pyroelectric layer between the first semiconductor region and the first conductive region, the first pyroelectric layer including a pyroelectric material in an orthorhombic configuration; and a second transistor including a second semiconductor region; a second conductive region; and a second pyroelectric layer between the second semiconductor region and the second conductive region, the second pyroelectric layer including the pyroelectric material in a tetragonal configuration.

Example 2 provides the device of example 1, where, in a cross-section of the first pyroelectric layer, at least 90% of the pyroelectric material is in the orthorhombic configuration.

Example 3 provides the device of example 2, where, in a cross-section of the second pyroelectric layer, at least 90% of the pyroelectric material is in the tetragonal configuration.

Example 4 provides the device of any of examples 1-3, where the pyroelectric material in the orthorhombic configuration has a different dielectric constant from the pyroelectric material in the tetragonal configuration.

Example 5 provides the device of any of examples 1-4, where applying a first temperature pulse at a first temperature to the pyroelectric material changes the configuration of the pyroelectric material from the orthorhombic configuration to the tetragonal configuration, and applying a second temperature pulse at a second temperature to the pyroelectric material changes the configuration of the pyroelectric material from the tetragonal configuration to the orthorhombic configuration.

Example 6 provides the device of example 5, where the first temperature pulse has a first duration, and the second temperature pulse has a second duration, the first duration less than the second duration.

Example 7 provides the device of example 5 or 6, where the first temperature is at least 100° C. higher than the second temperature.

Example 8 provides the device of any of examples 1-7, where the first transistor is in a first region, the second transistor is in a second region, and the device further includes a first heating element configured to apply the first temperature pulse to the first region; and a second heating element configured to apply the second temperature pulse to the second region.

Example 9 provides the device of any of examples 1-8, where the pyroelectric material is a dielectric material including oxygen and a metal.

Example 10 provides the device of example 9, where the metal is hafnium.

Example 11 provides the device of example 10, where the pyroelectric material further includes a dopant, where the dopant is one of zirconium, silicon, aluminum, tantalum, germanium, gallium, and titanium.

Example 12 provides the device of example 9, where the metal is zirconium.

Example 13 provides the device of example 12, where the pyroelectric material further includes a dopant, where the dopant is one of hafnium, silicon, aluminum, tantalum, germanium, gallium, and titanium.

Example 14 provides an assembly including a first device region including a first transistor, the first transistor including a pyroelectric material in a gate dielectric region; a second device region including a second transistor; and a heating element configured to apply a temperature pulse to the first device region.

Example 15 provides the assembly of example 14, where the heating element is configured to apply a first temperature pulse to induce a first crystal configuration in the pyroelectric material, and to apply a second temperature pulse to induce a second crystal configuration in the pyroelectric material.

Example 16 provides the assembly of example 15, where, in the first crystal configuration, the first transistor has a first threshold voltage, and in the second crystal configuration, the first transistor has a second threshold voltage different from the first threshold voltage.

Example 17 provides the assembly of any of examples 14-16, where the heating element is a first heating element, the assembly further including a second heating element configured to apply a temperature pulse to the second device region.

Example 18 provides the assembly of any of examples 14-17, where the heating element includes tungsten.

Example 19 provides a method including applying a first temperature pulse to a transistor; operating the transistor at a first threshold voltage; applying a second temperature pulse to the transistor, the second temperature pulse having a lower temperature than the first temperature pulse; and operating the transistor at a second threshold voltage different from the first threshold voltage.

Example 20 provides the method of example 19, where the transistor is a first transistor, the method further including operating a second transistor in a different device region at the second threshold voltage while operating the first transistor at the first threshold voltage.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

What is claimed is:

1. A device comprising:
a first transistor comprising:
a first semiconductor region;
a first conductive region; and
a first pyroelectric layer between the first semiconductor region and the first conductive region, the first pyroelectric layer comprising a pyroelectric material in an orthorhombic configuration; and
a second transistor comprising:
a second semiconductor region;
a second conductive region; and
a second pyroelectric layer between the second semiconductor region and the second conductive region, the second pyroelectric layer comprising the pyroelectric material in a tetragonal configuration.

2. The device of claim 1, wherein, in a cross-section of the first pyroelectric layer, at least 90% of the pyroelectric material is in the orthorhombic configuration.

3. The device of claim 2, wherein, in a cross-section of the second pyroelectric layer, at least 90% of the pyroelectric material is in the tetragonal configuration.

4. The device of claim 1, wherein the pyroelectric material in the orthorhombic configuration has a different dielectric constant from the pyroelectric material in the tetragonal configuration.

5. The device of claim 1, wherein applying a first temperature pulse at a first temperature to the pyroelectric material changes the configuration of the pyroelectric material from the orthorhombic configuration to the tetragonal configuration, and applying a second temperature pulse at a second temperature to the pyroelectric material changes the configuration of the pyroelectric material from the tetragonal configuration to the orthorhombic configuration.

6. The device of claim 5, wherein the first temperature pulse has a first duration, and the second temperature pulse has a second duration, the first duration less than the second duration.

7. The device of claim 5, wherein the first temperature is at least 100° C. higher than the second temperature.

8. The device of claim 5, wherein the first transistor is in a first region, the second transistor is in a second region, and the device further comprises:
a first heating element configured to apply the first temperature pulse to the first region; and
a second heating element configured to apply the second temperature pulse to the second region.

9. The device of claim 1, wherein the pyroelectric material is a dielectric material comprising oxygen and a metal.

10. The device of claim 9, wherein the metal is hafnium.

11. The device of claim 10, wherein the pyroelectric material further includes a dopant, wherein the dopant is one of zirconium, silicon, aluminum, tantalum, germanium, gallium, and titanium.

12. The device of claim 9, wherein the metal is zirconium.

13. The device of claim 12, wherein the pyroelectric material further includes a dopant, wherein the dopant is one of hafnium, silicon, aluminum, tantalum, germanium, gallium, and titanium.

14. An assembly comprising:
a first device region comprising a first transistor, the first transistor comprising a pyroelectric material in a gate dielectric region;
a second device region comprising a second transistor; and
a heating element configured to apply a temperature pulse to the first device region.

15. The assembly of claim 14, wherein the heating element is configured to apply a first temperature pulse to induce a first crystal configuration in the pyroelectric material, and to apply a second temperature pulse to induce a second crystal configuration in the pyroelectric material.

16. The assembly of claim 15, wherein, in the first crystal configuration, the first transistor has a first threshold voltage, and in the second crystal configuration, the first transistor has a second threshold voltage different from the first threshold voltage.

17. The assembly of claim 14, wherein the heating element is a first heating element, the assembly further comprising a second heating element configured to apply a second temperature pulse to the second device region.

18. The assembly of claim 14, wherein the heating element comprises tungsten.

19. A method comprising:
applying a first temperature pulse to a transistor;
operating the transistor at a first threshold voltage;
applying a second temperature pulse to the transistor, the second temperature pulse having a lower temperature than the first temperature pulse; and
operating the transistor at a second threshold voltage different from the first threshold voltage.

20. The method of claim 19, wherein the transistor is a first transistor, the method further comprising operating a second transistor in a different device region at the second threshold voltage while operating the first transistor at the first threshold voltage.
